(19) United States
(12) Patent Application Publication
(10) Pub. No.: US 2023/0420381 A1
(43) Pub. Date: Dec. 28, 2023

(54) TECHNOLOGIES FOR OVERLAY METROLOGY MARKS

(71) Applicant: Intel Corporation, Santa Clara, CA (US)

(72) Inventor: Martin N. Weiss, Portland, OR (US)

(73) Assignee: Intel Corporation, Santa Clara, CA (US)

(21) Appl. No.: 17/847,111

(22) Filed: Jun. 22, 2022

(51) Int. Cl. H01L 23/544; G03F 9/00; G03F 7/20

(52) U.S. Cl. CPC H01L 23/544; G03F 9/7076; G03F 7/70633; G03F 9/708; H01L 2223/54426

(57) ABSTRACT

Techniques for forming overlay metrology marks are disclosed. In the illustrative embodiment, a first overlay metrology mark is on a first layer of a semiconductor wafer, and a second metrology mark is formed on a second layer above the first layer. The overlay metrology marks are embodied as a series of grating lines. Looking downward at the overlay metrology marks, the two metrology marks form a moire pattern, with the light and dark regions of the moire pattern moving as the relative positions of the overlay metrology marks move. In the illustrative embodiment, at least one of the overlay metrology marks has non-uniform grating line spacing. As a result, the moire pattern is not identical if the overlay metrology mark is shifted by one grating line, allowing for a wider range of overlay errors to be detected.

### BACKGROUND

Modern integrated circuits may have a large number of layers with many precise connections between layers. In order to align one layer on top of another, a scanner monitors scanner marks to align a reticle or photomask to print a layer. After a layer is printed, overlay marks are used to determine if the layer was properly aligned. If it was not, it can be reworked. If it was, the next layer can be applied.

### BRIEF DESCRIPTION OF THE DRAWINGS

The concepts described herein are illustrated by way of example and not by way of limitation in the accompanying figures. For simplicity and clarity of illustration, elements illustrated in the figures are not necessarily drawn to scale. Where considered appropriate, reference labels have been repeated among the figures to indicate corresponding or analogous elements.

FIG. 1 is a top-down view of a wafer that includes one or more overlay metrology marks.

FIG. 2 is a cross-section view of the system of FIG. 1.

FIG. 3 is a top-down view of an overlay metrology mark.

FIG. 4 is a top-down view of an overlay metrology mark.

FIG. 5 is a top-down view of the overlay metrology marks of FIGS. 3 and 4 forming a periodic moire pattern.

FIG. 6 is a top-down view of the overlay metrology marks of FIGS. 3 and 4 forming a periodic moire pattern shifted relative to FIG. 5.

FIG. 7 is a top-down view of the overlay metrology marks of FIGS. 3 and 4 forming a periodic moire pattern relative to FIGS. 5 and 6.

FIG. 8 is a top-down view of a non-uniform overlay metrology mark.

FIG. 9 is a top-down view of the overlay metrology marks of FIGS. 3 and 8 forming a nonperiodic moire pattern.

FIG. 10 is a top-down view of the overlay metrology marks of FIGS. 3 and 8 forming a nonperiodic moire pattern shifted relative to FIG. 9.

FIG. 11 is a simplified flow diagram of at least one embodiment of a method for creating the system of FIG. 1.

FIG. 12 is a top view of a wafer and dies that may be included in a microelectronic assembly, in accordance with any of the embodiments disclosed herein.

FIG. 13 is a cross-sectional side view of an integrated circuit device that may be included in a microelectronic assembly, in accordance with any of the embodiments disclosed herein.

FIGS. 14A-14D are perspective views of example planar, FinFET, gate-all-around, and stacked gate-all-around transistors.

FIG. 15 is a cross-sectional side view of an integrated circuit device assembly that may include a microelectronic assembly, in accordance with any of the embodiments disclosed herein.

FIG. 16 is a block diagram of an example electrical device that may include a microelectronic assembly, in accordance with any of the embodiments disclosed herein.

### DETAILED DESCRIPTION OF THE DRAWINGS

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact, and “coupled” may indicate elements co-operate or interact, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, a substrate assembly feature, such as a through width, that is described as having substantially a listed dimension can vary within a few percent of the listed dimension.

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate and an integrated circuit component attached to a printed circuit board that send signals to or receives signals from other integrated circuit components or electronic devices attached to the printed circuit board.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

As used herein, the terms “upper”/“lower” or “above”/“below” may refer to relative locations of an object (e.g., the surfaces described above), especially in light of examples shown in the attached figures, rather than an absolute location of an object. For example, an upper surface of an apparatus may be on an opposite side of the apparatus from a lower surface of the object, and the upper surface may be facing upward generally only when viewed in a particular way. As another example, a first object above a second object may be on or near an “upper” surface of the second object rather than near a “lower” surface of the object, and the first object may be truly above the second object only when the two objects are viewed in a particular way.

The disclosed embodiments may be implemented, in some cases, in hardware, firmware, software, or any combination thereof. The disclosed embodiments may also be implemented as instructions carried by or stored on a transitory or non-transitory machine-readable (e.g., computer-readable) storage medium, which may be read and executed by one or more processors. A machine-readable storage medium may be embodied as any storage device, mechanism, or other physical structure for storing or transmitting information in a form readable by a machine (e.g., a volatile or non-volatile memory, a media disc, or other media device).

References are made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

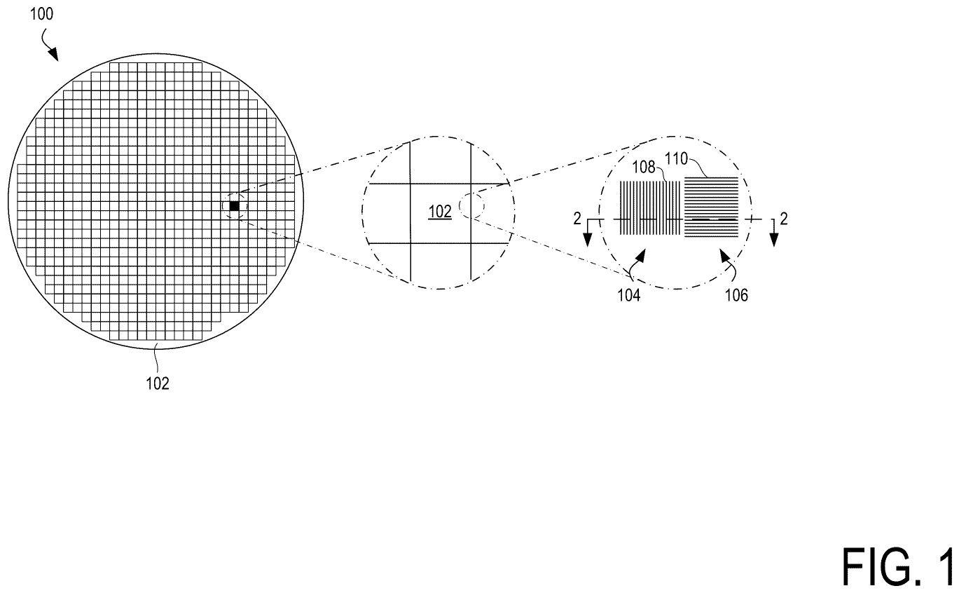

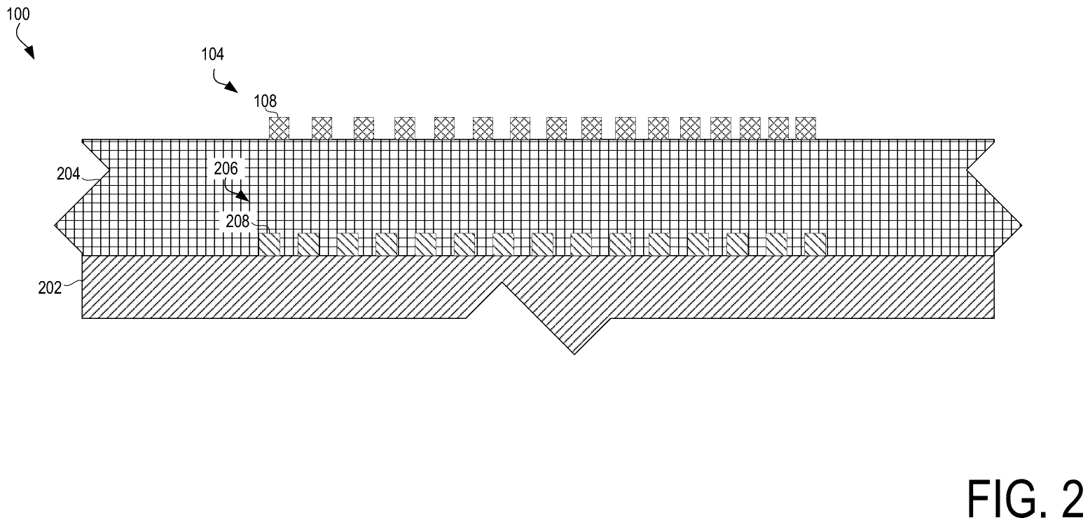

Referring now to FIGS. 1 and 2, a top view of a wafer 100 and dies 102 is shown. FIG. 2 shows a cross-sectional view of one part of the wafer 100. The wafer 100 may be composed of semiconductor material and may include one or more dies 102 having integrated circuit structures formed on a surface of the wafer 100. The individual dies 102 may be a repeating unit of an integrated circuit product that includes any suitable integrated circuit. After the fabrication of the semiconductor product is complete, the wafer 100 may undergo a singulation process in which the dies 102 are separated from one another to provide discrete “chips” of the integrated circuit product. The die 102 may include one or more transistors, supporting circuitry to route electrical signals to the transistors, passive components (e.g., signal traces, resistors, capacitors, or inductors), and/or any other integrated circuit components.

The illustrative wafer 100 includes one or more overlay metrology marks 104, 106. Overlay metrology mark 104 may be made up of several grating lines 108, and overlay metrology mark 106 may be made up of several orthogonal grating lines 110. As discussed in more detail below, the overlay metrology marks 104, 106 may be used to check alignment of reticle prints on the wafer 100. In the illustrative embodiment, overlay metrology mark 104 is used to check alignment in one direction, and orthogonal overlay metrology mark 106 is used to check alignment in an orthogonal direction. A wafer 100 may include any suitable number of overlay metrology marks 104, 106 at any suitable layer and in any suitable position. In some embodiment, some or all of the overlay metrology marks 104, 106 may be in a scribe line of the wafer 100. In other embodiments, the overlay metrology marks 104, 106 may be positioned outside of a scribe line of the wafer 100.

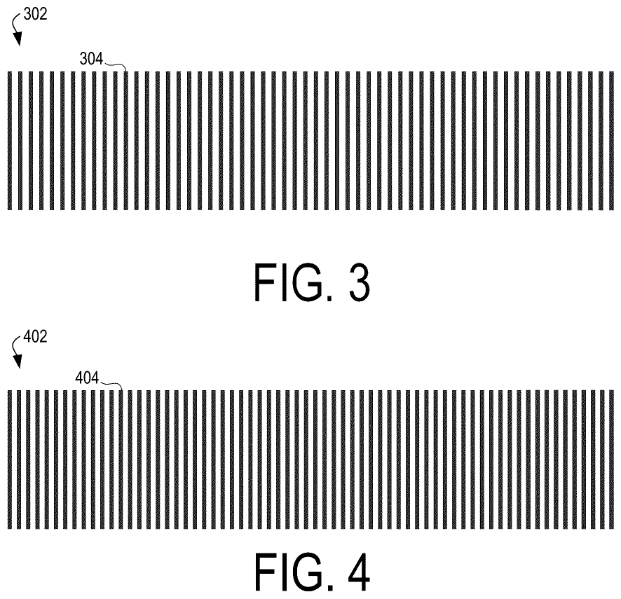

As shown in FIG. 2, the overlay metrology mark 104 may be on a top surface of the wafer 100 at a particular stage of processing the wafer 100. The wafer 100 may have a lower layer 202 on which a first overlay metrology mark 206 is formed, and the overlay metrology mark 104 may be an upper overlay metrology mark 104 on a second layer 204 on top of the first layer 202. In use and as described in more detail below in regard to FIGS. 3-8, the upper overlay metrology mark 104 and the lower overlay metrology mark 206, when viewed from above, form a moire pattern that indicates the position of the upper overlay metrology mark 104 relative to the position of the lower overlay metrology mark 206.

Each of the grating lines 108, 208 that form the overlay metrology marks 104, 206 may be any suitable material, such as silicon, silicon oxide, metal, dielectric, and/or any other suitable material that reflects or absorbs light in a different manner than adjacent material. In some embodiments, the grating lines 108, 208 may be embodied as, e.g., gates or spaces between gates, rows of vias, and/or the like. The grating lines 108, 208 may absorb more or less light than surrounding material. In some embodiments, the grating lines 108 of the upper overlay metrology mark 104 may be part of a temporary photomask layer.

In the illustrative embodiment, the pitch of the overlay metrology marks 104, 206 may be, e.g., 200-500 nanometers. In other embodiments, the pitch of the overlay metrology marks 104, 206 may be any suitable value, such as 50-2,000 nanometers. In the illustrative embodiment, the pitch of the overlay metrology marks 104, 206 is small enough that a microscope used to examine the overlay metrology marks 104, 206 on a wafer 100 cannot resolve individual grating lines 108, 208 using visible light. Rather, the light and dark regions of the moire pattern formed by two overlay metrology marks can be resolved (see below in regard to FIGS. 3-10 for more detail on moire patterns). In the illustrative embodiment, the width of each overlay grating line 108, 208 is about half the pitch. In other embodiments, the width of each overlay grating line 108, 208 may be any suitable amount, such as 10-90% of the pitch.

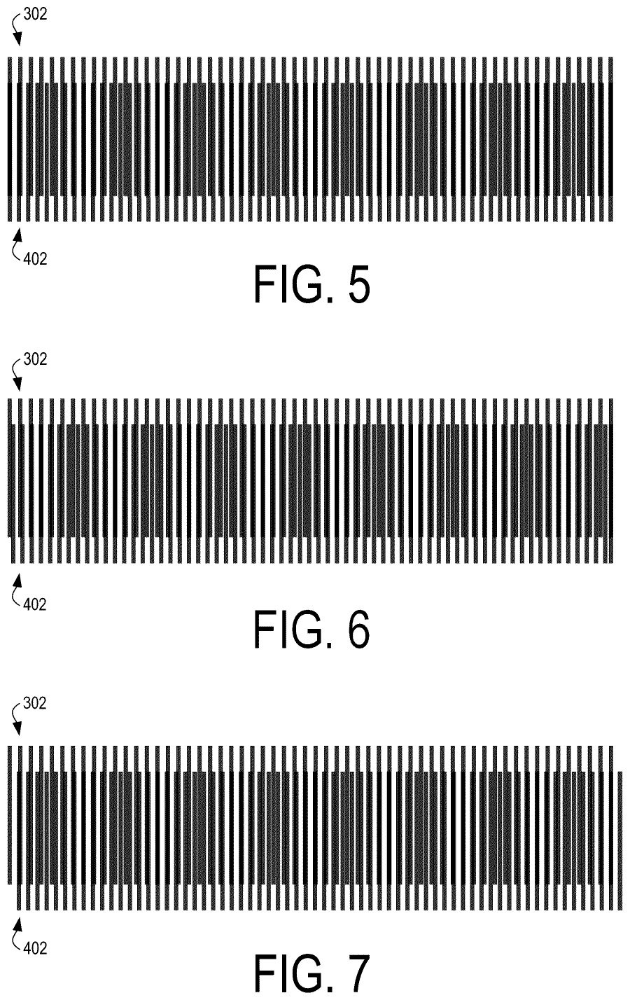

Referring now to FIGS. 3-7, in one embodiment, a first overlay metrology mark 302 with first grating lines 304 is shown in FIG. 3, and a second overlay metrology mark 402 with second grating lines 404 is shown in FIG. 4. In the illustrative embodiment, the pitch for the overlay metrology mark 402 is slightly smaller than the pitch for the overlay metrology mark 302. In the example shown in FIGS. 3 and 4, overlay metrology mark 302 has a pitch that is about 15% higher that of overlay metrology mark 402. Over the span of the overlay metrology marks 302, 402, the overlay metrology mark 402 has eight more grating lines 404 than the overlay metrology mark 302. As a result, when viewed with one overlay metrology mark 302 on top of the other overlay metrology mark 402 as shown in FIG. 5, eight alternating light and dark fringes are visible. The pattern formed by viewing one overlay metrology mark 302 on top of another overlay metrology mark 402 is called a moire pattern or moire interference fringe. For evenly-spaced grating lines, if the pitch of the first overlay metrology mark is G₁ and the pitch of the second overlay metrology mark is G₂, then the pitch of the resultant moire interference fringe has a period P given by P=G₁*G₂/(G₂ G₁).

In the illustrative embodiment, one overlay metrology mark is on a first layer (or reticle print) and the other overlay metrology mark is on a second layer over the first layer. Any error in the overlay of the second layer on the first will result in a shift in relative position between the two overlay metrology marks. When the two overlay metrology marks are shifted by a distance of x relative to each other (in the direction perpendicular to the grating lines), then the fringe pattern shifts by x*G₁/(G₂−G₁). This technique can be used to measure small overlay errors with high detectability, since the shift in the observed fringe pattern is equal to the actual overlay multiplied by an amplification factor G₁/(G₂−G₁). The amplification factor may be any suitable amount, such as 2-50.

FIGS. 5-7 show an example of the behavior of a periodic moire pattern caused by two overlay metrology marks 302, 402. The overlay metrology marks 302, 402 are shown vertically offset in order for the individual lines to be identified. In use, the overlay metrology marks 302, 402 on a wafer 100 will not be vertically offset. With the leftmost grating lines overlapping, the moire pattern is as shown in FIG. 5. The moire pattern in FIG. 5 is periodic, with dark and light regions alternating with a period of about eight grating lines 304 in this example. In the presence of overlay error between the two reticle prints, the entire fringe pattern shifts, while maintaining the periodicity. FIG. 6 shows the moire pattern with the overlay metrology mark 402 is shifted by one-third of the spacing between grating lines 404. As can be seen from FIGS. 5 and 6, the light and dark regions of the moire pattern shift more than the actual overlay error between the two gratings that form the overlay metrology mark 402.

A limitation of that approach is that when the fringe pattern shifts by more than half of the fringe period, then the overlay between the two gratings cannot be uniquely determined. For example, FIG. 7 shows the moire pattern when the overlay metrology mark 402 is shifted by one grating line 404. As can be seen by comparing FIG. 5 and FIG. 7, the position of light and dark regions of the moire pattern are unchanged. In general, a shift of more than half of a grating line leads to an ambiguous moire pattern. When used in determining overlay error of two layers (or reticle prints) of a wafer, it may lead to wafers with large overlay incorrectly being reported as having small overlay. This is known as “wrap-around error” and would result in incorrect in-line disposition and end-of-line yield risk. To avoid this, the effective dynamic range of the overlay measurement is limited to x<G2/2.

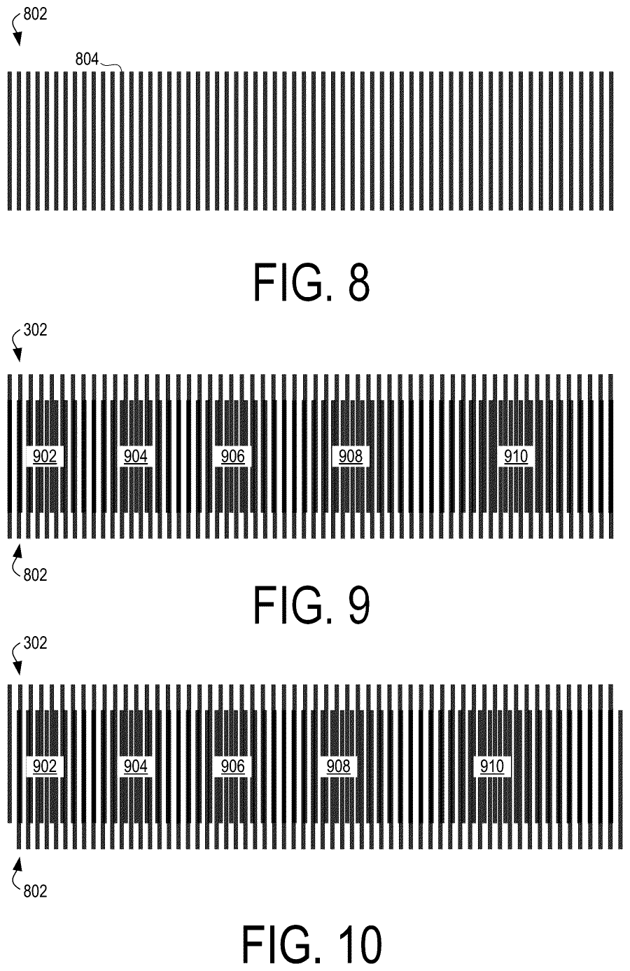

Referring now to FIGS. 8-10, in one embodiment, an overlay metrology marker 802 has several non-uniformly-spaced grating lines 804. In the illustrative embodiment, the pitch between the grating lines 804 increases linearly by about 10% over the span of the overlay metrology marker 802. Such an overlay metrology marker may be referred to as a linearly chirped overlay metrology marker. In other embodiments, the pitch between grating lines 804 may increase or decrease by any suitable amount, such as 1-50%. The pitch between grating lines 804 may increase or decrease according to any suitable function, such as a linear function, a polynomial, a step function, a periodic function, etc.

When the overlay metrology marker 802 is positioned over the overlay metrology marker 302 with a constant pitch, a moire pattern as shown in FIG. 9 is visible. The moire pattern includes dark regions 902, 904, 906, 908, and 910. As for the moire pattern formed by overlay metrology marker 302 and overlay metrology marker 402, a small change in position will result in a relatively larger change in position of the dark regions 902, 904, 906, 908, 910. However, unlike the moire pattern formed by overlay metrology marker 302 and overlay metrology marker 402, a change of one full grating line 804 does not result in an identical moire pattern. For example, FIG. 10 shows the moire pattern of the overlay metrology marker 802 shifted by one grating line 804 (at the pitch on the left side of the overlay metrology marker 802). Near the region where the pitch is about the same as the amount of shift (i.e., on the left side of FIG. 10), dark region 902 in FIG. 10 does not shift much compared to dark region 902 in FIG. 9. However, as the pitch of the overlay metrology mark 802 increases, the dark regions move relative to the corresponding dark region in FIG. 9. As such, the moire pattern shown in FIG. 10 is easily distinguishable from the moire pattern shown in FIG. 9.

In the illustrative embodiment described above, one overlay metrology mark 302 has uniformly-spaced grating lines 304, and one overlay metrology mark 802 has non-uniformly-spaced grating lines 804. In other embodiments, each of two overlay metrology marks patterns that form a moire pattern may have non-uniformly-spaced grating lines, such as grating lines with opposite linear chirp. More generally, each of two such metrology marks may have any of the non-uniform-spaced grating lines described above.

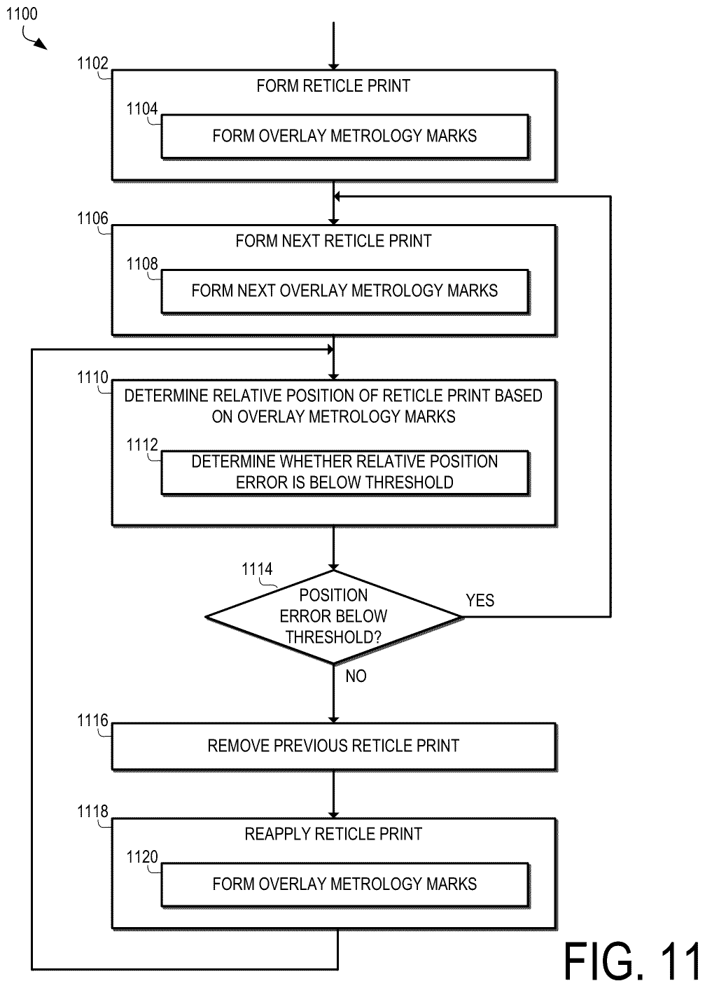

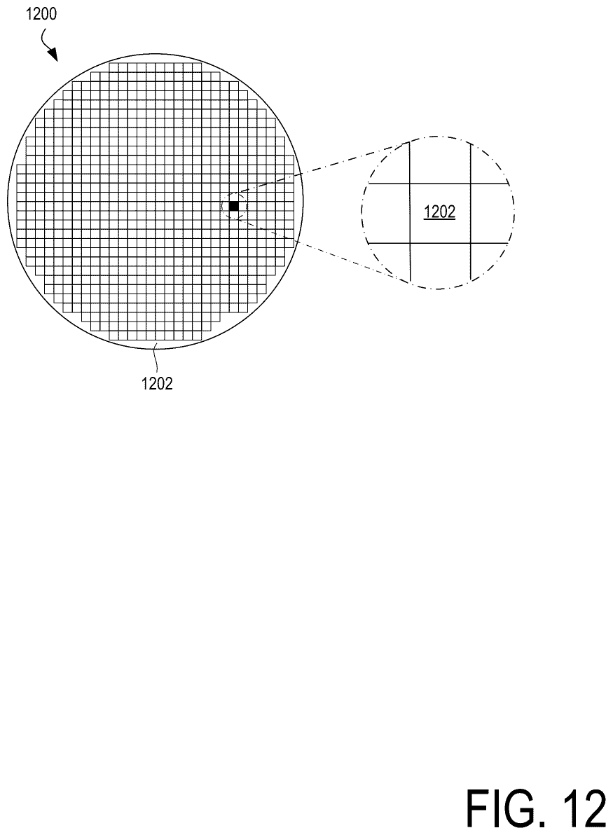

Referring now to FIG. 11, in one embodiment, a method 1100 for using overlay metrology marks is shown. The method 1100 may be executed by a technician and/or by one or more automated machines. In some embodiments, one or more machines may be programmed to do some or all of the steps of the method 1100. Such a machine may include, e.g., a memory, a processor, data storage, etc. The memory and/or data storage may store instructions that, when executed by the machine, causes the machine to perform some or all of the steps of the method 1100. The method 1100 may use any suitable set of techniques that are used in semiconductor processing, such as chemical vapor deposition, atomic layer deposition, physical layer deposition, molecular beam epitaxy, layer transfer, photolithography, ion implantation, dry etching, wet etching, thermal treatments, flip chip, layer transfer, magnetron sputter deposition, pulsed laser deposition, etc. It should be appreciated that the method 1100 is merely one embodiment of a method to create the wafer 100, and other methods may be used to create the wafer 100. In some embodiments, steps of the method 1100 may be performed in a different order than that shown in the flowchart.

The method 1100 begins in block 1102, in which a reticle print (or layer) is formed on the wafer 100. As part of forming the reticle print, in block 1104, one or more overlay metrology marks are formed. Any suitable number of overlay metrology marks may be formed in any suitable position, such as inside or outside of scribe lines. The overlay metrology marks may include an array of grating lines. In the illustrative embodiment, the grating lines are straight. In other embodiments, the grating lines may not be straight. Each of the grating lines that form the overlay metrology mark may be any suitable material, such as silicon, silicon oxide, metal, dielectric, and/or any other suitable material that reflects or absorbs light in a different manner than adjacent material. The pitch between grating lines of the overlay metrology mark may be uniform or non-uniform. The pitch between grating lines of the overlay metrology mark with non-uniform grating line spacing may increase or decrease according to any suitable function, such as a linear function, a polynomial, a step function, a periodic function, etc.

In block 1106, the next reticle print (or layer) is formed. In block 1108, as part of forming the next reticle print, one or more overlay metrology marks are formed. In the illustrative embodiment, at least some of the overlay metrology marks are formed over the overlay metrology marks from a previous layer or reticle print. The overlay metrology marks may be similar to those formed in block 1104, a description of which will not be repeated. In some cases, the overlay metrology mark may be part of a temporary photomask layer, to be removed after an overlay error is checked.

In block 1110, a relative position of the reticle print compared to the previous one is determined based on the overlay metrology marks. As described above in regard to FIGS. 3-10, the moire pattern formed by two overlay metrology marks is shifted based on the relative position of the two overlay metrology marks. In particular, if one of the overlay metrology marks has non-uniform grating line spacing, then the relative position of the two overlay metrology marks can be determined even if the difference is more than half of a grating line. In block 1112, the relative position is compared to a threshold amount. The threshold amount may be determined based on an acceptable overlay error for the particular reticle print. The threshold amount may be any suitable value, such as 1-1,000 nanometers.

In block 1114, if the position error is below the threshold, then the reticle print (or layer) is acceptable, and the method 1100 loops back to block 1106 to form the next reticle print. If the position error is above the threshold, then the reticle print is not acceptable, and the method 1100 proceeds to block 1116. In block 1116, the previous reticle print is removed. In block 1118, the reticle print is reapplied. In block 1120, the overlay metrology marks are reformed as well. The method 1100 then loops back to block 1110 to determine the relative position of the reticle print compared to the previous one.

It should be appreciated that the process of forming the wafer 100 may include additional steps not included herein.

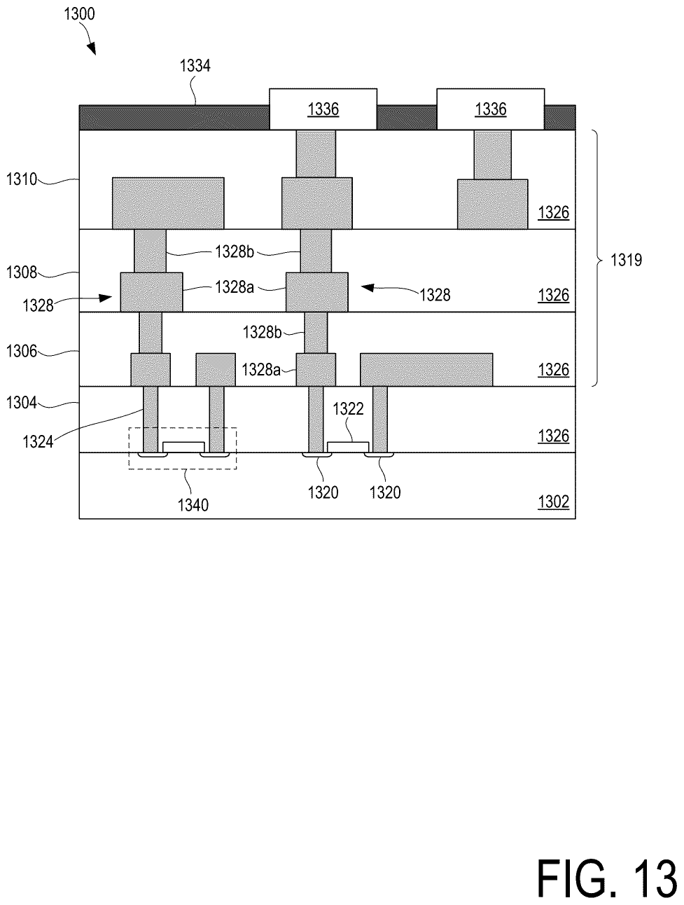

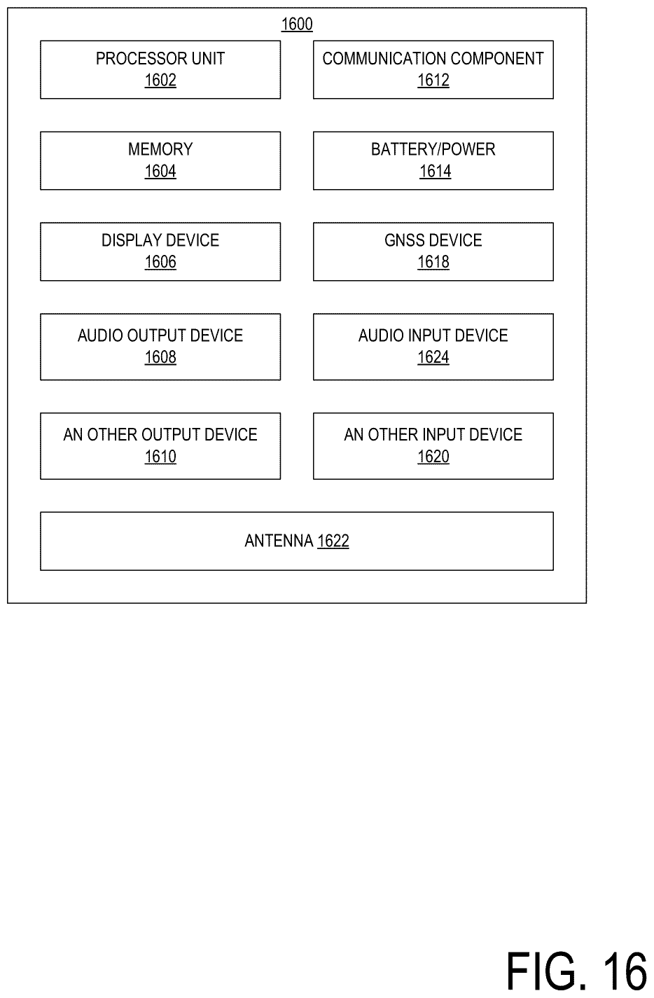

FIG. 12 is a top view of a wafer 1200 and dies 1202 that may be included in any of the embodiments disclosed herein (e.g., as any suitable ones of the wafers 100). The wafer 1200 may be composed of semiconductor material and may include one or more dies 1202 having integrated circuit structures formed on a surface of the wafer 1200. The individual dies 1202 may be a repeating unit of an integrated circuit product that includes any suitable integrated circuit. After the fabrication of the semiconductor product is complete, the wafer 1200 may undergo a singulation process in which the dies 1202 are separated from one another to provide discrete “chips” of the integrated circuit product. The die 1202 may include one or more transistors (e.g., some of the transistors 1340 of FIG. 13, discussed below), supporting circuitry to route electrical signals to the transistors, passive components (e.g., signal traces, resistors, capacitors, or inductors), and/or any other integrated circuit components. In some embodiments, the wafer 1200 or the die 1202 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1202. For example, a memory array formed by multiple memory devices may be formed on a same die 1202 as a processor unit (e.g., the processor unit 1602 of FIG. 16) or other logic that is configured to store information in the memory devices or execute instructions stored in the memory array. Various systems disclosed herein may be manufactured using a die-to-wafer assembly technique in which some dies are attached to a wafer 1200 that include others of the dies, and the wafer 1200 is subsequently singulated.

FIG. 13 is a cross-sectional side view of an integrated circuit device 1300 that may be included in any of the wafers 100 disclosed herein. One or more of the integrated circuit devices 1300 may be included in one or more dies 1202 (FIG. 12). The integrated circuit device 1300 may be formed on a die substrate 1302 (e.g., the wafer 1200 of FIG. 12) and may be included in a die (e.g., the die 1202 of FIG. 12). The die substrate 1302 may be a semiconductor substrate composed of semiconductor material systems including, for example, n-type or p-type materials systems (or a combination of both). The die substrate 1302 may include, for example, a crystalline substrate formed using a bulk silicon or a silicon-on-insulator (SOI) substructure. In some embodiments, the die substrate 1302 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1302. Although a few examples of materials from which the die substrate 1302 may be formed are described here, any material that may serve as a foundation for an integrated circuit device 1300 may be used. The die substrate 1302 may be part of a singulated die (e.g., the dies 1202 of FIG. 12) or a wafer (e.g., the wafer 1200 of FIG. 12).

The integrated circuit device 1300 may include one or more device layers 1304 disposed on the die substrate 1302. The device layer 1304 may include features of one or more transistors 1340 (e.g., metal oxide semiconductor field-effect transistors (MOSFETs)) formed on the die substrate 1302. The transistors 1340 may include, for example, one or more source and/or drain (S/D) regions 1320, a gate 1322 to control current flow between the S/D regions 1320, and one or more S/D contacts 1324 to route electrical signals to/from the S/D regions 1320. The transistors 1340 may include additional features not depicted for the sake of clarity, such as device isolation regions, gate contacts, and the like. The transistors 1340 are not limited to the type and configuration depicted in FIG. 13 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

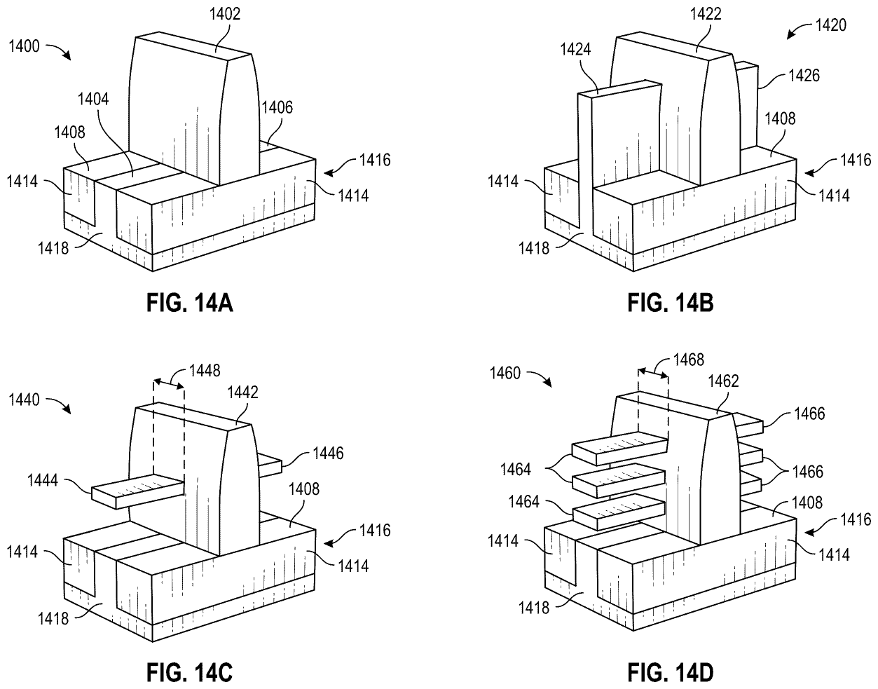

FIGS. 14A-14D are simplified perspective views of example planar, FinFET, gate-all-around, and stacked gate-all-around transistors. The transistors illustrated in FIGS. 14A-14D are formed on a substrate 1416 having a surface 1408. Isolation regions 1414 separate the source and drain regions of the transistors from other transistors and from a bulk region 1418 of the substrate 1416.

FIG. 14A is a perspective view of an example planar transistor 1400 comprising a gate 1402 that controls current flow between a source region 1404 and a drain region 1406. The transistor 1400 is planar in that the source region 1404 and the drain region 1406 are planar with respect to the substrate surface 1408.

FIG. 14B is a perspective view of an example FinFET transistor 1420 comprising a gate 1422 that controls current flow between a source region 1424 and a drain region 1426. The transistor 1420 is non-planar in that the source region 1424 and the drain region 1426 comprise “fins” that extend upwards from the substrate surface 1428. As the gate 1422 encompasses three sides of the semiconductor fin that extends from the source region 1424 to the drain region 1426, the transistor 1420 can be considered a tri-gate transistor. FIG. 14B illustrates one S/D fin extending through the gate 1422, but multiple S/D fins can extend through the gate of a FinFET transistor.

FIG. 14C is a perspective view of a gate-all-around (GAA) transistor 1440 comprising a gate 1442 that controls current flow between a source region 1444 and a drain region 1446. The transistor 1440 is non-planar in that the source region 1444 and the drain region 1446 are elevated from the substrate surface 1428.

FIG. 14D is a perspective view of a GAA transistor 1460 comprising a gate 1462 that controls current flow between multiple elevated source regions 1464 and multiple elevated drain regions 1466. The transistor 1460 is a stacked GAA transistor as the gate controls the flow of current between multiple elevated S/D regions stacked on top of each other. The transistors 1440 and 1460 are considered gate-all-around transistors as the gates encompass all sides of the semiconductor portions that extends from the source regions to the drain regions. The transistors 1440 and 1460 can alternatively be referred to as nanowire, nanosheet, or nanoribbon transistors depending on the width (e.g., widths 1448 and 1468 of transistors 1440 and 1460, respectively) of the semiconductor portions extending through the gate.

Returning to FIG. 13, a transistor 1340 may include a gate 1322 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1340 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1340 along the source-channel-drain direction, the gate electrode may consist of a U-shaped structure that includes a bottom portion substantially parallel to the surface of the die substrate 1302 and two sidewall portions that are substantially perpendicular to the top surface of the die substrate 1302. In other embodiments, at least one of the metal layers that form the gate electrode may simply be a planar layer that is substantially parallel to the top surface of the die substrate 1302 and does not include sidewall portions substantially perpendicular to the top surface of the die substrate 1302. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1320 may be formed within the die substrate 1302 adjacent to the gate 1322 of individual transistors 1340. The S/D regions 1320 may be formed using an implantation/diffusion process or an etching/deposition process, for example. In the former process, dopants such as boron, aluminum, antimony, phosphorous, or arsenic may be ion-implanted into the die substrate 1302 to form the S/D regions 1320. An annealing process that activates the dopants and causes them to diffuse farther into the die substrate 1302 may follow the ion-implantation process. In the latter process, the die substrate 1302 may first be etched to form recesses at the locations of the S/D regions 1320. An epitaxial deposition process may then be carried out to fill the recesses with material that is used to fabricate the S/D regions 1320. In some implementations, the S/D regions 1320 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1320 may be formed using one or more alternate semiconductor materials such as germanium or a group III-V material or alloy. In further embodiments, one or more layers of metal and/or metal alloys may be used to form the S/D regions 1320.

Electrical signals, such as power and/or input/output (I/O) signals, may be routed to and/or from the devices (e.g., transistors 1340) of the device layer 1304 through one or more interconnect layers disposed on the device layer 1304 (illustrated in FIG. 13 as interconnect layers 1306-1310). For example, electrically conductive features of the device layer 1304 (e.g., the gate 1322 and the S/D contacts 1324) may be electrically coupled with the interconnect structures 1328 of the interconnect layers 1306-1310. The one or more interconnect layers 1306-1310 may form a metallization stack (also referred to as an “ILD stack”) 1319 of the integrated circuit device 1300.

The interconnect structures 1328 may be arranged within the interconnect layers 1306-1310 to route electrical signals according to a wide variety of designs; in particular, the arrangement is not limited to the particular configuration of interconnect structures 1328 depicted in FIG. 13. Although a particular number of interconnect layers 1306-1310 is depicted in FIG. 13, embodiments of the present disclosure include integrated circuit devices having more or fewer interconnect layers than depicted.

In some embodiments, the interconnect structures 1328 may include lines 1328a and/or vias 1328b filled with an electrically conductive material such as a metal. The lines 1328a may be arranged to route electrical signals in a direction of a plane that is substantially parallel with a surface of the die substrate 1302 upon which the device layer 1304 is formed. For example, the lines 1328a may route electrical signals in a direction in and out of the page and/or in a direction across the page. The vias 1328b may be arranged to route electrical signals in a direction of a plane that is substantially perpendicular to the surface of the die substrate 1302 upon which the device layer 1304 is formed. In some embodiments, the vias 1328b may electrically couple lines 1328a of different interconnect layers 1306-1310 together.

The interconnect layers 1306-1310 may include a dielectric material 1326 disposed between the interconnect structures 1328, as shown in FIG. 13. In some embodiments, dielectric material 1326 disposed between the interconnect structures 1328 in different ones of the interconnect layers 1306-1310 may have different compositions; in other embodiments, the composition of the dielectric material 1326 between different interconnect layers 1306-1310 may be the same. The device layer 1304 may include a dielectric material 1326 disposed between the transistors 1340 and a bottom layer of the metallization stack as well. The dielectric material 1326 included in the device layer 1304 may have a different composition than the dielectric material 1326 included in the interconnect layers 1306-1310; in other embodiments, the composition of the dielectric material 1326 in the device layer 1304 may be the same as a dielectric material 1326 included in any one of the interconnect layers 1306-1310.

A first interconnect layer 1306 (referred to as Metal 1 or “M1”) may be formed directly on the device layer 1304. In some embodiments, the first interconnect layer 1306 may include lines 1328a and/or vias 1328b, as shown. The lines 1328a of the first interconnect layer 1306 may be coupled with contacts (e.g., the S/D contacts 1324) of the device layer 1304. The vias 1328b of the first interconnect layer 1306 may be coupled with the lines 1328a of a second interconnect layer 1308.

The second interconnect layer 1308 (referred to as Metal 2 or “M2”) may be formed directly on the first interconnect layer 1306. In some embodiments, the second interconnect layer 1308 may include via 1328b to couple the lines 1328 of the second interconnect layer 1308 with the lines 1328a of a third interconnect layer 1310. Although the lines 1328a and the vias 1328b are structurally delineated with a line within individual interconnect layers for the sake of clarity, the lines 1328a and the vias 1328b may be structurally and/or materially contiguous (e.g., simultaneously filled during a dual-damascene process) in some embodiments.

The third interconnect layer 1310 (referred to as Metal 3 or “M3”) (and additional interconnect layers, as desired) may be formed in succession on the second interconnect layer 1308 according to similar techniques and configurations described in connection with the second interconnect layer 1308 or the first interconnect layer 1306. In some embodiments, the interconnect layers that are “higher up” in the metallization stack 1319 in the integrated circuit device 1300 (i.e., farther away from the device layer 1304) may be thicker that the interconnect layers that are lower in the metallization stack 1319, with lines 1328a and vias 1328b in the higher interconnect layers being thicker than those in the lower interconnect layers.

The integrated circuit device 1300 may include a solder resist material 1334 (e.g., polyimide or similar material) and one or more conductive contacts 1336 formed on the interconnect layers 1306-1310. In FIG. 13, the conductive contacts 1336 are illustrated as taking the form of bond pads. The conductive contacts 1336 may be electrically coupled with the interconnect structures 1328 and configured to route the electrical signals of the transistor(s) 1340 to external devices. For example, solder bonds may be formed on the one or more conductive contacts 1336 to mechanically and/or electrically couple an integrated circuit die including the integrated circuit device 1300 with another component (e.g., a printed circuit board). The integrated circuit device 1300 may include additional or alternate structures to route the electrical signals from the interconnect layers 1306-1310; for example, the conductive contacts 1336 may include other analogous features (e.g., posts) that route the electrical signals to external components.

In some embodiments in which the integrated circuit device 1300 is a double-sided die, the integrated circuit device 1300 may include another metallization stack (not shown) on the opposite side of the device layer(s) 1304. This metallization stack may include multiple interconnect layers as discussed above with reference to the interconnect layers 1306-1310, to provide conductive pathways (e.g., including conductive lines and vias) between the device layer(s) 1304 and additional conductive contacts (not shown) on the opposite side of the integrated circuit device 1300 from the conductive contacts 1336.

In other embodiments in which the integrated circuit device 1300 is a double-sided die, the integrated circuit device 1300 may include one or more through silicon vias (TSVs) through the die substrate 1302; these TSVs may make contact with the device layer(s) 1304, and may provide conductive pathways between the device layer(s) 1304 and additional conductive contacts (not shown) on the opposite side of the integrated circuit device 1300 from the conductive contacts 1336. In some embodiments, TSVs extending through the substrate can be used for routing power and ground signals from conductive contacts on the opposite side of the integrated circuit device 1300 from the conductive contacts 1336 to the transistors 1340 and any other components integrated into the die 1300, and the metallization stack 1319 can be used to route I/O signals from the conductive contacts 1336 to transistors 1340 and any other components integrated into the die 1300.

Multiple integrated circuit devices 1300 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

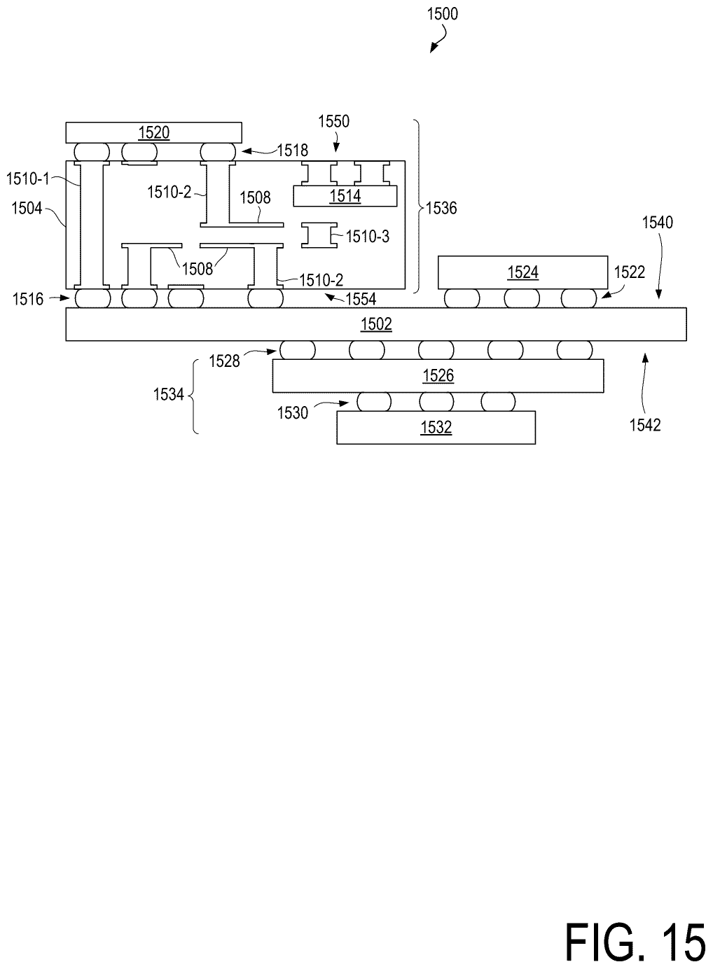

FIG. 15 is a cross-sectional side view of an integrated circuit device assembly 1500 that may be included in any of the wafers 100 disclosed herein. The integrated circuit device assembly 1500 includes a number of components disposed on a circuit board 1502 (which may be a motherboard, system board, mainboard, etc.). The integrated circuit device assembly 1500 includes components disposed on a first face 1540 of the circuit board 1502 and an opposing second face 1542 of the circuit board 1502; generally, components may be disposed on one or both faces 1540 and 1542.

In some embodiments, the circuit board 1502 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1502. In other embodiments, the circuit board 1502 may be a non-PCB substrate. The integrated circuit device assembly 1500 illustrated in FIG. 15 includes a package-on-interposer structure 1536 coupled to the first face 1540 of the circuit board 1502 by coupling components 1516. The coupling components 1516 may electrically and mechanically couple the package-on-interposer structure 1536 to the circuit board 1502, and may include solder balls (as shown in FIG. 15), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1536 may include an integrated circuit component 1520 coupled to an interposer 1504 by coupling components 1518. The coupling components 1518 may take any suitable form for the application, such as the forms discussed above with reference to the coupling components 1516. Although a single integrated circuit component 1520 is shown in FIG. 15, multiple integrated circuit components may be coupled to the interposer 1504; indeed, additional interposers may be coupled to the interposer 1504. The interposer 1504 may provide an intervening substrate used to bridge the circuit board 1502 and the integrated circuit component 1520.

The integrated circuit component 1520 may be a packaged or unpacked integrated circuit product that includes one or more integrated circuit dies (e.g., the die 1202 of FIG. 12, the integrated circuit device 1300 of FIG. 13) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1520, a single monolithic integrated circuit die comprises solder bumps attached to contacts on the die. The solder bumps allow the die to be directly attached to the interposer 1504. The integrated circuit component 1520 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1520 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1520 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1520 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1504 may spread connections to a wider pitch or reroute a connection to a different connection. For example, the interposer 1504 may couple the integrated circuit component 1520 to a set of ball grid array (BGA) conductive contacts of the coupling components 1516 for coupling to the circuit board 1502. In the embodiment illustrated in FIG. 15, the integrated circuit component 1520 and the circuit board 1502 are attached to opposing sides of the interposer 1504; in other embodiments, the integrated circuit component 1520 and the circuit board 1502 may be attached to a same side of the interposer 1504. In some embodiments, three or more components may be interconnected by way of the interposer 1504.

In some embodiments, the interposer 1504 may be formed as a PCB, including multiple metal layers separated from one another by layers of dielectric material and interconnected by electrically conductive vias. In some embodiments, the interposer 1504 may be formed of an epoxy resin, a fiberglass-reinforced epoxy resin, an epoxy resin with inorganic fillers, a ceramic material, or a polymer material such as polyimide. In some embodiments, the interposer 1504 may be formed of alternate rigid or flexible materials that may include the same materials described above for use in a semiconductor substrate, such as silicon, germanium, and other group III-V and group IV materials. The interposer 1504 may include metal interconnects 1508 and vias 1510, including but not limited to through hole vias 1510-1 (that extend from a first face 1550 of the interposer 1504 to a second face 1554 of the interposer 1504), blind vias 1510-2 (that extend from the first or second faces 1550 or 1554 of the interposer 1504 to an internal metal layer), and buried vias 1510-3 (that connect internal metal layers).

In some embodiments, the interposer 1504 can comprise a silicon interposer. Through silicon vias (TSV) extending through the silicon interposer can connect connections on a first face of a silicon interposer to an opposing second face of the silicon interposer. In some embodiments, an interposer 1504 comprising a silicon interposer can further comprise one or more routing layers to route connections on a first face of the interposer 1504 to an opposing second face of the interposer 1504.

The interposer 1504 may further include embedded devices 1514, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1504. The package-on-interposer structure 1536 may take the form of any of the package-on-interposer structures known in the art. In embodiments where the interposer is a non-printed circuit board

The integrated circuit device assembly 1500 may include an integrated circuit component 1524 coupled to the first face 1540 of the circuit board 1502 by coupling components 1522. The coupling components 1522 may take the form of any of the embodiments discussed above with reference to the coupling components 1516, and the integrated circuit component 1524 may take the form of any of the embodiments discussed above with reference to the integrated circuit component 1520.

The integrated circuit device assembly 1500 illustrated in FIG. 15 includes a package-on-package structure 1534 coupled to the second face 1542 of the circuit board 1502 by coupling components 1528. The package-on-package structure 1534 may include an integrated circuit component 1526 and an integrated circuit component 1532 coupled together by coupling components 1530 such that the integrated circuit component 1526 is disposed between the circuit board 1502 and the integrated circuit component 1532. The coupling components 1528 and 1530 may take the form of any of the embodiments of the coupling components 1516 discussed above, and the integrated circuit components 1526 and 1532 may take the form of any of the embodiments of the integrated circuit component 1520 discussed above. The package-on-package structure 1534 may be configured in accordance with any of the package-on-package structures known in the art.

FIG. 16 is a block diagram of an example electrical device 1600 that may include one or more of the dies from the wafers 100 disclosed herein. For example, any suitable ones of the components of the electrical device 1600 may include one or more of the integrated circuit device assemblies 1500, integrated circuit components 1520, integrated circuit devices 1300, or integrated circuit dies 1202 disclosed herein. A number of components are illustrated in FIG. 16 as included in the electrical device 1600, but any one or more of these components may be omitted or duplicated, as suitable for the application. In some embodiments, some or all of the components included in the electrical device 1600 may be attached to one or more motherboards mainboards, or system boards. In some embodiments, one or more of these components are fabricated onto a single system-on-a-chip (SoC) die.

Additionally, in various embodiments, the electrical device 1600 may not include one or more of the components illustrated in FIG. 16, but the electrical device 1600 may include interface circuitry for coupling to the one or more components. For example, the electrical device 1600 may not include a display device 1606, but may include display device interface circuitry (e.g., a connector and driver circuitry) to which a display device 1606 may be coupled. In another set of examples, the electrical device 1600 may not include an audio input device 1624 or an audio output device 1608, but may include audio input or output device interface circuitry (e.g., connectors and supporting circuitry) to which an audio input device 1624 or audio output device 1608 may be coupled.

The electrical device 1600 may include one or more processor units 1602 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1602 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1600 may include a memory 1604, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1604 may include memory that is located on the same integrated circuit die as the processor unit 1602. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1600 can comprise one or more processor units 1602 that are heterogeneous or asymmetric to another processor unit 1602 in the electrical device 1600. There can be a variety of differences between the processing units 1602 in a system in terms of a spectrum of metrics of merit including architectural, microarchitectural, thermal, power consumption characteristics, and the like. These differences can effectively manifest themselves as asymmetry and heterogeneity among the processor units 1602 in the electrical device 1600.

In some embodiments, the electrical device 1600 may include a communication component 1612 (e.g., one or more communication components). For example, the communication component 1612 can manage wireless communications for the transfer of data to and from the electrical device 1600. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1612 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1612 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1612 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1612 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1612 may operate in accordance with other wireless protocols in other embodiments. The electrical device 1600 may include an antenna 1622 to facilitate wireless communications and/or to receive other wireless communications (such as AM or FM radio transmissions).

In some embodiments, the communication component 1612 may manage wired communications, such as electrical, optical, or any other suitable communication protocols (e.g., IEEE 802.3 Ethernet standards). As noted above, the communication component 1612 may include multiple communication components. For instance, a first communication component 1612 may be dedicated to shorter-range wireless communications such as Wi-Fi or Bluetooth, and a second communication component 1612 may be dedicated to longer-range wireless communications such as global positioning system (GPS), EDGE, GPRS, CDMA, WiMAX, LTE, EV-DO, or others. In some embodiments, a first communication component 1612 may be dedicated to wireless communications, and a second communication component 1612 may be dedicated to wired communications.

The electrical device 1600 may include battery/power circuitry 1614. The battery/power circuitry 1614 may include one or more energy storage devices (e.g., batteries or capacitors) and/or circuitry for coupling components of the electrical device 1600 to an energy source separate from the electrical device 1600 (e.g., AC line power).

The electrical device 1600 may include a display device 1606 (or corresponding interface circuitry, as discussed above). The display device 1606 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1600 may include an audio output device 1608 (or corresponding interface circuitry, as discussed above). The audio output device 1608 may include any embedded or wired or wirelessly connected external device that generates an audible indicator, such speakers, headsets, or earbuds.

The electrical device 1600 may include an audio input device 1624 (or corresponding interface circuitry, as discussed above). The audio input device 1624 may include any embedded or wired or wirelessly connected device that generates a signal representative of a sound, such as microphones, microphone arrays, or digital instruments (e.g., instruments having a musical instrument digital interface (MIDI) output). The electrical device 1600 may include a Global Navigation Satellite System (GNSS) device 1618 (or corresponding interface circuitry, as discussed above), such as a Global Positioning System (GPS) device. The GNSS device 1618 may be in communication with a satellite-based system and may determine a geolocation of the electrical device 1600 based on information received from one or more GNSS satellites, as known in the art.

The electrical device 1600 may include an other output device 1610 (or corresponding interface circuitry, as discussed above). Examples of the other output device 1610 may include an audio codec, a video codec, a printer, a wired or wireless transmitter for providing information to other devices, or an additional storage device.

The electrical device 1600 may include an other input device 1620 (or corresponding interface circuitry, as discussed above). Examples of the other input device 1620 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1600 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1600 may be any other electronic device that processes data. In some embodiments, the electrical device 1600 may comprise multiple discrete physical components. Given the range of devices that the electrical device 1600 can be manifested as in various embodiments, in some embodiments, the electrical device 1600 can be referred to as a computing device or a computing system.

As used in any embodiment herein, the term “module” refers to logic that may be implemented in a hardware component or device, software or firmware running on a processor, or a combination thereof, to perform one or more operations consistent with the present disclosure. Software may be embodied as a software package, code, instructions, instruction sets and/or data recorded on non-transitory computer readable storage mediums. Firmware may be embodied as code, instructions or instruction sets and/or data that are hard-coded (e.g., nonvolatile) in memory devices. As used in any embodiment herein, the term “circuitry” can comprise, for example, singly or in any combination, hardwired circuitry, programmable circuitry such as computer processors comprising one or more individual instruction processing cores, state machine circuitry, and/or firmware that stores instructions executed by programmable circuitry. Modules described herein may, collectively or individually, be embodied as circuitry that forms a part of one or more devices. Thus, any of the modules can be implemented as circuitry. A computing system referred to as being programmed to perform a method can be programmed to perform the method via software, hardware, firmware or combinations thereof.

The computer-executable instructions or computer program products as well as any data created and used during implementation of the disclosed technologies can be stored on one or more tangible or non-transitory computer-readable storage media, such as optical media discs (e.g., DVDs, CDs), volatile memory components (e.g., DRAM, SRAM), or non-volatile memory components (e.g., flash memory, solid-state drives, chalcogenide-based phase-change non-volatile memories). Computer-readable storage media can be contained in computer-readable storage devices such as solid-state drives, USB flash drives, and memory modules. Alternatively, the computer-executable instructions may be performed by specific hardware components that contain hardwired logic for performing all or a portion of disclosed methods, or by any combination of computer-readable storage media and hardware components.

The computer-executable instructions can be part of, for example, a dedicated software application or a software application that is accessed via a web browser or other software application (such as a remote computing application). Such software can be read and executed by, for example, a single computing device or in a network environment using one or more networked computers. Further, it is to be understood that the disclosed technology is not limited to any specific computer language or program. For instance, the disclosed technologies can be implemented by software written in C++, Java, Perl, Python, JavaScript, Adobe Flash, or any other suitable programming language. Likewise, the disclosed technologies are not limited to any particular computer or type of hardware.

Furthermore, any of the software-based embodiments (comprising, for example, computer-executable instructions for causing a computer to perform any of the disclosed methods) can be uploaded, downloaded or remotely accessed through a suitable communication means. Such suitable communication means include, for example, the Internet, the World Wide Web, an intranet, cable (including fiber optic cable), magnetic communications, electromagnetic communications (including RF, microwave, and infrared communications), electronic communications, or other such communication means.

As used in this application and in the claims, a list of items joined by the term “and/or” can mean any combination of the listed items. For example, the phrase “A, B and/or C” can mean A; B; C; A and B; A and C; B and C; or A, B and C. As used in this application and in the claims, a list of items joined by the term “at least one of” can mean any combination of the listed terms. For example, the phrase “at least one of A, B or C” can mean A; B; C; A and B; A and C; B and C; or A, B and C. Moreover, as used in this application and in the claims, a list of items joined by the term “one or more of” can mean any combination of the listed terms. For example, the phrase “one or more of A, B and C” can mean A; B; C; A and B; A and C; B and C; or A, B, and C.

The disclosed methods, apparatuses and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

### EXAMPLES

Illustrative examples of the technologies disclosed herein are provided below. An embodiment of the technologies may include any one or more, and any combination of, the examples described below.

Example 1 includes a die comprising a first reticle print; a second reticle print; a first overlay metrology mark on the first reticle print, the first overlay metrology mark comprising a plurality of parallel lines; and a second overlay metrology mark on the second reticle print, wherein the second overlay metrology mark comprises a plurality of non-uniformly-spaced parallel lines.

Example 2 includes the subject matter of Example 1, and wherein, when viewed from above the die, the first overlay metrology mark and the second overlay metrology mark form a moire pattern without a constant period.

Example 3 includes the subject matter of any of Examples 1 and 2, and further including a third overlay metrology mark on the first reticle print, the third overlay metrology mark comprising a plurality of parallel lines; and a fourth overlay metrology mark on the second reticle print, wherein the fourth overlay metrology mark comprises a plurality of non-uniformly-spaced parallel lines, wherein the plurality of parallel lines of the third overlay metrology mark are orthogonal to the plurality of parallel lines of the first overlay metrology mark, wherein the plurality of non-uniformly-spaced parallel lines of the fourth overlay metrology mark are orthogonal to the plurality of non-uniformly-spaced parallel lines of the second overlay metrology mark.

Example 4 includes the subject matter of any of Examples 1-3, and wherein a pitch of the first overlay metrology mark is between 200 and 500 nanometers.

Example 5 includes the subject matter of any of Examples 1-4, and wherein a pitch of the second overlay metrology mark is between 200 and 500 nanometers.

Example 6 includes the subject matter of any of Examples 1-5, and wherein the plurality of non-uniformly-spaced parallel lines have a spacing that is linearly dependent on position.

Example 7 includes the subject matter of any of Examples 1-6, and wherein the plurality of parallel lines of the first overlay metrology mark is a plurality of non-uniformly-spaced parallel lines.

Example 8 includes the subject matter of any of Examples 1-7, and wherein the first overlay metrology mark is above the second overlay metrology mark.

Example 9 includes the subject matter of any of Examples 1-8, and wherein the first overlay metrology mark is below the second overlay metrology mark.

Example 10 includes the subject matter of any of Examples 1-9, and wherein the die is a part of a wafer.

Example 11 includes the subject matter of any of Examples 1-10, and wherein the die is singulated from a wafer.

Example 12 includes a method comprising applying a first reticle print to a wafer, wherein applying the first reticle print comprises forming a first overlay metrology mark, the first overlay metrology mark comprising a plurality of parallel lines; and applying a second reticle print to the wafer, wherein applying the second reticle print comprises forming a second overlay metrology mark over the first overlay metrology mark, the second overlay metrology mark comprising a plurality of non-uniformly-spaced parallel lines.

Example 13 includes the subject matter of Example 12, and wherein, when viewed from above the wafer, the first overlay metrology mark and the second overlay metrology mark form a moire pattern without a constant period.

Example 14 includes the subject matter of any of Examples 12 and 13, and further including determining, based on a moire pattern formed by viewing the first overlay metrology mark and the second overlay metrology mark, a position of the second overlay metrology mark relative to the first overlay metrology mark.

Example 15 includes the subject matter of any of Examples 12-14, and further including determining whether an error in the position of the second overlay metrology mark relative to the first overlay metrology mark is above a threshold; and (i) if the error is below the threshold, applying a third reticle print over the second reticle print in response to a determination that the error is below the threshold or (ii) if the error is above the threshold, removing the second reticle print in response to a determination that the error is above the threshold.

Example 16 includes the subject matter of any of Examples 12-15, and wherein applying the first reticle print comprises forming a third overlay metrology mark, the third overlay metrology mark comprising a plurality of parallel lines, wherein applying the second reticle print comprises forming a fourth overlay metrology mark, wherein the fourth overlay metrology mark comprises a plurality of non-uniformly-spaced parallel lines, wherein the plurality of parallel lines of the third overlay metrology mark are orthogonal to the plurality of parallel lines of the first overlay metrology mark, wherein the plurality of non-uniformly-spaced parallel lines of the fourth overlay metrology mark are orthogonal to the plurality of non-uniformly-spaced parallel lines of the second overlay metrology mark.

Example 17 includes the subject matter of any of Examples 12-16, and wherein the second overlay metrology mark comprises a photomask material.

Example 18 includes the subject matter of any of Examples 12-17, and wherein a pitch of the first overlay metrology mark is between 200 and 500 nanometers.

Example 19 includes the subject matter of any of Examples 12-18, and wherein a pitch of the second overlay metrology mark is between 200 and 500 nanometers.

Example 20 includes the subject matter of any of Examples 12-19, and wherein the plurality of non-uniformly-spaced parallel lines have a spacing that is linearly dependent on position.

Example 21 includes the subject matter of any of Examples 12-20, and wherein the plurality of parallel lines of the first overlay metrology mark is a plurality of non-uniformly-spaced parallel lines.

Example 22 includes a die comprising a first reticle print; a second reticle print above the first reticle print; and overlay metrology marking means to uniquely determine a relative position of the second reticle print relative to the first reticle print.

Example 23 includes the subject matter of Example 22, and wherein the overlay metrology marking means comprises a first overlay metrology marking means on the first reticle print and a second overlay metrology marking means on the second reticle print.

Example 24 includes the subject matter of any of Examples 22 and 23, and wherein, when viewed from above the die, the first overlay metrology marking means and the second overlay metrology marking means form a moire pattern without a constant period.

Example 25 includes the subject matter of any of Examples 22-24, and further including a third overlay metrology marking means on the first reticle print, the third overlay metrology marking means comprising a plurality of parallel lines; and a fourth overlay metrology marking means on the second reticle print, wherein the fourth overlay metrology marking means comprises a plurality of non-uniformly-spaced parallel lines, wherein the plurality of parallel lines of the third overlay metrology marking means are orthogonal to the plurality of parallel lines of the first overlay metrology marking means, wherein the plurality of non-uniformly-spaced parallel lines of the fourth overlay metrology marking means are orthogonal to the plurality of non-uniformly-spaced parallel lines of the second overlay metrology marking means.

Example 26 includes the subject matter of any of Examples 22-25, and wherein a pitch of the first overlay metrology marking means is between 200 and 500 nanometers.

Example 27 includes the subject matter of any of Examples 22-26, and wherein a pitch of the second overlay metrology marking means is between 200 and 500 nanometers.

Example 28 includes the subject matter of any of Examples 22-27, and wherein the die is a part of a wafer.

Example 29 includes the subject matter of any of Examples 22-28, and wherein the die is singulated from a wafer.

1. A die comprising:
a first reticle print;
a second reticle print;
a first overlay metrology mark on the first reticle print, the first overlay metrology mark comprising a plurality of parallel lines; and
a second overlay metrology mark on the second reticle print, wherein the second overlay metrology mark comprises a plurality of non-uniformly-spaced parallel lines.

2. The die of claim 1, wherein, when viewed from above the die, the first overlay metrology mark and the second overlay metrology mark form a moire pattern without a constant period.

3. The die of claim 1, further comprising:
a third overlay metrology mark on the first reticle print, the third overlay metrology mark comprising a plurality of parallel lines; and
a fourth overlay metrology mark on the second reticle print, wherein the fourth overlay metrology mark comprises a plurality of non-uniformly-spaced parallel lines,
wherein the plurality of parallel lines of the third overlay metrology mark are orthogonal to the plurality of parallel lines of the first overlay metrology mark,
wherein the plurality of non-uniformly-spaced parallel lines of the fourth overlay metrology mark are orthogonal to the plurality of non-uniformly-spaced parallel lines of the second overlay metrology mark.

4. The die of claim 1, wherein a pitch of the first overlay metrology mark is between 200 and 500 nanometers.

5. The die of claim 4, wherein a pitch of the second overlay metrology mark is between 200 and 500 nanometers.

6. The die of claim 1, wherein the plurality of non-uniformly-spaced parallel lines have a spacing that is linearly dependent on position.

7. The die of claim 1, wherein the plurality of parallel lines of the first overlay metrology mark is a plurality of non-uniformly-spaced parallel lines.

8. The die of claim 1, wherein the first overlay metrology mark is above the second overlay metrology mark.

9. The die of claim 1, wherein the first overlay metrology mark is below the second overlay metrology mark.

10. The die of claim 1, wherein the die is a part of a wafer.

11. The die of claim 1, wherein the die is singulated from a wafer.

12. A method comprising:
applying a first reticle print to a wafer, wherein applying the first reticle print comprises forming a first overlay metrology mark, the first overlay metrology mark comprising a plurality of parallel lines; and
applying a second reticle print to the wafer, wherein applying the second reticle print comprises forming a second overlay metrology mark over the first overlay metrology mark, the second overlay metrology mark comprising a plurality of non-uniformly-spaced parallel lines.

13. The method of claim 12, wherein, when viewed from above the wafer, the first overlay metrology mark and the second overlay metrology mark form a moire pattern without a constant period.

14. The method of claim 12, further comprising determining a position of a first reticle print relative to a second reticle print based on a moire pattern formed by viewing the first overlay metrology mark and the second overlay metrology mark.

15. The method of claim 14, further comprising:
determining whether an error in the position of the second overlay metrology mark relative to the first overlay metrology mark is above a threshold; and
(i) if the error is below the threshold, applying a third reticle print over the second reticle print in response to a determination that the error is below the threshold or (ii) if the error is above the threshold, removing the second reticle print in response to a determination that the error is above the threshold.

16. The method of claim 12, wherein applying the first reticle print comprises forming a third overlay metrology mark, the third overlay metrology mark comprising a plurality of parallel lines,
wherein applying the second reticle print comprises forming a fourth overlay metrology mark, wherein the fourth overlay metrology mark comprises a plurality of non-uniformly-spaced parallel lines,
wherein the plurality of parallel lines of the third overlay metrology mark are orthogonal to the plurality of parallel lines of the first overlay metrology mark,
wherein the plurality of non-uniformly-spaced parallel lines of the fourth overlay metrology mark are orthogonal to the plurality of non-uniformly-spaced parallel lines of the second overlay metrology mark.

17. The method of claim 12, wherein the second overlay metrology mark comprises a photomask material.

18. The method of claim 12, wherein the plurality of non-uniformly-spaced parallel lines have a spacing that is linearly dependent on position.

19. The method of claim 12, wherein the plurality of parallel lines of the first overlay metrology mark is a plurality of non-uniformly-spaced parallel lines.

20. A die comprising:
a first reticle print;
a second reticle print above the first reticle print; and
overlay metrology marking means to uniquely determine a relative position of the second reticle print relative to the first reticle print.

21. The die of claim 20, wherein the overlay metrology marking means comprises a first overlay metrology marking means on the first reticle print and a second overlay metrology marking means on the second reticle print.

22. The die of claim 21, wherein, when viewed from above the die, the first overlay metrology marking means and the second overlay metrology marking means form a moire pattern without a constant period.

23. The die of claim 22, further comprising:
a third overlay metrology marking means on the first reticle print, the third overlay metrology marking means comprising a plurality of parallel lines; and
a fourth overlay metrology marking means on the second reticle print, wherein the fourth overlay metrology marking means comprises a plurality of non-uniformly-spaced parallel lines,
wherein the plurality of parallel lines of the third overlay metrology marking means are orthogonal to the plurality of parallel lines of the first overlay metrology marking means,
wherein the plurality of non-uniformly-spaced parallel lines of the fourth overlay metrology marking means are orthogonal to the plurality of non-uniformly-spaced parallel lines of the second overlay metrology marking means.

24. The die of claim 22, wherein a pitch of the first overlay metrology marking means is between 200 and 500 nanometers.

25. The die of claim 24, wherein a pitch of the second overlay metrology marking means is between 200 and 500 nanometers.
